(19) United States
(12) Patent Application Publication
(10) Pub. No.: US 2022/0358260 A1
(43) Pub. Date: Nov. 10, 2022

(54) METHOD FOR DETERMINING A TOPOLOGY OF A DEFINED BOUNDED SURFACE FOR DEWATERING SAID SURFACE

(71) Applicant: UDS Urbane Daten-System GMBH, Hamburg (DE)

(72) Inventors: Roman BÖRNCHEN, Hamburg (DE); Mitja ROEDER, Hamburg (DE)

(73) Assignee: UDS Urbane Daten-System GMBH, Hamburg (DE)

(21) Appl. No.: 17/640,797

(22) PCT Filed: Sep. 5, 2019
(86) PCT No.: PCT/EP2019/073778

§ 371 Date: Mar. 4, 2022

(51) Int. Cl. G06F 30/13; E04D 13/04

(52) U.S. Cl. CPC G06F 30/13; E04D 13/0477; E04D 13/0481

(57) ABSTRACT

The invention relates to a method for determining a topology of a defined, bounded surface (1) for dewatering said surface by means of at least one specified dewatering point (21), so that the surface (1) comprises a monotonically increasing slope starting from the dewatering point (21) to a collision point (16), said method avoiding the disadvantages of eth prior art and determining in a more efficient, simple, and less error-prone manner a topology of a defined, bounded area (1) for dewatering the same by means of at least one specified dewatering point (21), so that the surface (1) comprises a monotonically increasing slope, starting from the dewatering point (21) to a collision point (16), and proposes that the topology is determined such that the surface (1) is subdivided into individual surface elements (2) each having at least one plane (3), wherein a slope in a first direction and/or a second direction perpendicular to the first direction is successively determined in every plane (3) for each area element (2), starting from the dewatering point (21).

### CROSS-REFERENCE TO RELATED APPLICATIONS

This application is the US National Phase Under 371 of International Patent Application No. PCT/EP2019/073778, entitled “METHOD FOR DETERMINING A TOPOLOGY OF A DEFINED BOUNDED SURFACE FOR DEWATERING SAID SURFACE”, naming Roman BÖRNCHEN and Mitja ROEDER as inventors, and filed Sep. 5, 2019, the subject matter of which is hereby incorporated herein by reference.

The present invention relates to a method for determining a topology of a defined bounded surface for dewatering said surface by means of at least one specified dewatering point, so that the surface comprises a monotonically increasing slope starting from the dewatering point to a collision point, for example a roof edge and/or a transition to a light well and/or a transition to an elevator shaft.

The present invention further relates to a configuration plan saved on a data storage medium for a surface for depicting in two or three dimensions slopes determined for individual surface elements as instructions for creating a structure of a topology for dewatering a defined, bounded surface according to the determined slopes, wherein the plates correspond to the dimensions and/or the geometric shape of the individual surface elements.

The present invention further relates to the structure of a topology of a defined, bounded surface, comprising individual plates in a dimension and/or a geometric shape of individual surface elements.

The present invention further relates to a software for implementing a method according to claims 1 through 20.

Such a method for automatically configuring sloped roofs is known from the prior art. Said method can be used for automatically configuring sloped roofs with no collision points, such as internal corners. Manual rework is necessary, however, for configuring sloped roofs having internal corners. A disadvantage of the method from the prior art is that only topologies for surfaces without collision points can thereby be automatically generated.

Creating topologies for surfaces having arbitrarily many collision points is time-consuming, complex, and subject to error.

A configuration plan saved on a data storage medium is known from the prior art. Said configuration plan can, however, only be produced by manual rework and thus not completely automated. It is thereby disadvantageous that the manual rework is subject to error and time-consuming.

Against this background, the object of the invention is to disclose a method of the type indicated above for avoiding the disadvantages of the prior art and enabling more efficient, simple, and less error-prone determining of a topology of a defined bounded surface for dewatering the same by means of at least one specified dewatering point, so that the surface comprises a monotonically increasing slope starting from the dewatering point up to a collision point.

The object is achieved according to the invention by means of a generic method in which a slope in a first direction and/or a second direction aligned perpendicular to the first direction is successively determined in every plane for each surface element, starting from the dewatering point. In this manner, according to the invention, a topology can be generated automatically for a surface having arbitrarily many collision points, such as internal corners. This opens up improved potential with respect to saving material as well as securely dewatering every point of the surface.

In an advantageous embodiment of the invention, the method comprises a step in which a throat slope is determined for at least one, preferably for every surface element directly adjacent to the dewatering point, in that at least two, preferably two planes are determined for the surface element, wherein the surface normal of at least two planes intersect and/or are inclined in a first direction and/or in a second direction aligned perpendicular to the first direction. The slopes thus implemented on the surface elements serve for reliably dewatering every point on the surface into the dewatering point. The dewatering point preferably is at an intersection of the imaginary lines dividing the surface into individual surface elements. A throat slope for all four surface elements adjacent in the diagonal direction can thus be determined for minimal material usage and minimal material cutting waste.

In a preferred embodiment of the invention, the method comprises a step in which the at least two, preferably two planes of a surface element having a throat slope form a recess in the diagonal direction along the surface element. The trough thus formed on the surface element along a diagonal opens up the possibility of defining a continuous dewatering path over the surface, wherein water is guided to the dewatering point. Within the dewatering path, flat transitions, without steps at which water could accumulate, arise due to equalization of the heights of the individual surface elements according to the method according to the invention.

In an advantageous embodiment of the invention, the method comprises a step in which the magnitude and/or direction of the slope of the at least two, preferably two planes of a surface element is determined as a function of the slope of the at least two, preferably two planes of the surface elements adjacent in a diagonal direction and/or in a first direction and/or in a second direction aligned perpendicular to the first direction. An optimal slope of the planes relative to each other and in the direction of the dewatering point is thus determined for each of the surface elements. A method for automatically assigning a slope and arbitrarily many collision points to a surface is thus disclosed, said method being able to be integrated in programs such as AutoCAD, for example, with little effort. The method according to the invention is preferably a computer-implemented method. Diverse information about the course of the slope of the surface and the associated dewatering situation and collision points is also collected and can be used for optimal assignment.

In a preferred embodiment of the invention, the method comprises a step in which a throat slope is determined for a surface element directly adjacent in a diagonal direction to a surface element having a throat slope. The water is thus guided by the monotonically decreasing slope in the direction of the dewatering point from every point on the surface, without a buildup being generated by an increase in the slope at any point.

In an advantageous embodiment of the invention, the method comprises a step in which a slope is determined for a surface element adjacent in a first direction and/or a second direction aligned perpendicular to the first direction to a surface element having a throat slope, in that a slope of the plane of the surface element is monotonically increasing and/or decreasing in a first direction and/or a second direction aligned perpendicular to the first direction. This opens up the possibility of reliable dewatering of surface elements having a plane in the direction of the continuous dewatering path over the surface, so that no recesses are formed at any point on the surface at which water remains.

In an advantageous embodiment of the invention, the method comprises a step in which a slope is determined for a surface element adjacent in a first direction and/or a second direction aligned perpendicular to the first direction to a surface element having a slope. The optimal assignment for reliable dewatering is thus determined automatically for each individual surface element, one after the other. An optimal use of materials can be ensured in conjunction therewith and thus a reduction in material waste achieved. This leads to savings in resources and enables cost savings when assigning a slope to surfaces.

In an advantageous embodiment of the invention, the method comprises a step in which the slope of a surface element adjacent in a first direction and/or a second direction aligned perpendicular to the first direction to a surface element having a slope is determined, as a throat slope, wherein the surface element having the slope comprises at least one collision point in a first direction and/or in a second direction perpendicular to the first direction. This opens up the possibility of automatically detecting and assigning surface elements having a collision point, for example at the end of a roof, and/or a transition to a light well and/or a transition to an elevator shaft, so that the dewatering takes place around the collision point and water is also drained in the direction of the dewatering point starting from said points.

In a preferred embodiment of the invention, the method comprises a step in which the slope of a plane of a surface element having a slope in the direction of at least one collision point is determined as a slope offset from the collision point by 90°. Water is thus guided around the collision point at said point in the direction of the dewatering point of the surface and does not flow directly toward the collision point, at which buildup of water can then occur. This ensures reliable dewatering at every point, particularly at collision points of the surface.

In an advantageous embodiment of the invention, the method comprises a step in which, for a plane of a surface element adjacent in a first direction and/or a second direction aligned perpendicular to the first direction to a surface element having a slope, wherein the slopes are each aligned toward each other, a flat slope is determined, wherein the slope of the plane is zero, wherein the magnitude of the slope is equal to the magnitude of the slope of the adjacent surface element having the greater magnitude. A dewatering path having a monotonically decreasing slope in the direction of the dewatering point thus arises over the entire surface, and no increase of the slope unable to be overcome by the draining water occurs at any of the points.

In a preferred embodiment of the invention, the method comprises a step in which, for a surface element adjacent in a first direction and/or a second direction aligned perpendicular to the first direction to a surface element having a throat slope, and adjacent in the diagonal direction to a surface element having a slope, a ridge slope is determined, wherein the at least two, preferably two planes of the surface element intersect and/or are inclined in the opposite direction of the slope of the surface normal of the surface element having the throat slope in a first direction and/or in a second direction aligned perpendicular to the first direction. This enables automated assigning of a slope to a surface for reliably dewatering while optimally determining the number of plates to be placed on the surface.

In an advantageous embodiment of the invention, the method comprises a step in which, for a surface element adjacent in a first direction and/or a second direction aligned perpendicular to the first direction to a surface element having a throat slope, and adjacent in the diagonal direction to a surface element having a slope, a ridge slope is determined, wherein the surface normal of the at least two, preferably two planes of the surface element intersect and/or are inclined in the opposite direction of the slope of the surface normal of the surface element having the throat slope in a first direction and/or in a second direction aligned perpendicular to the first direction. This enables automatically assigning the surface elements so that water is guided on both sides of the rise in the direction of the dewatering point in each case by means of the sloped planes of a surface element having a rise, and thus a dewatering path having a monotonically decreasing slope in the direction of the dewatering point is indicated.

In a preferred embodiment of the invention, the method comprises a step in which it is determined that the at least two, preferably two planes of a surface element having a throat slope form a rise in the diagonal direction along the surface element. It is thus the case that no transition able to cause buildup of the water occurs at any transition between two surface elements of different heights.

In an advantageous embodiment of the invention, the method comprises a step in which a ridge slope is determined for a surface element in which two slopes in different directions are perpendicular to each other. This opens up the possibility that the forming of sinks in which water is collected and not drained to the dewatering point is prevented within the surface, so that reliable dewatering of the surface is ensured. The material usage can also be optimized in that the material waste is reduced.

In a preferred embodiment of the invention, the method comprises a step in which, for a surface element directly adjacent in a first direction and/or in a second direction aligned perpendicular to the first direction and/or in a diagonal direction to at least two, preferably two surface elements having a throat slope directly adjacent to each other in a first direction and/or in a second direction aligned perpendicular to the first direction, wherein the throat slope is monotonically increasing in the direction of a point in each case, a slope is determined, wherein the surface normal of the surface element is parallel to the surface normal of the surface element having the throat slope. Water is thus guided, by means of the automated assigning, starting from a collection point in a monotonically decreasing dewatering path and thus on the shortest path to the dewatering point of the surface.

In an advantageous embodiment of the invention, the method comprises a step in which, for a surface element present between two surface elements each having a throat slope in the first direction and/or the second direction aligned perpendicular to the first direction, wherein the throat slope is monotonically increasing in the direction of a point in each case, a flat slope is determined, wherein the magnitude of the slope is determined to be the magnitude of the slope of the adjacent surface element having the greater magnitude. It is thus the case that no transition able to cause buildup of the water occurs at any transition between two surface elements of different heights.

In a preferred embodiment of the invention, the method comprises a step in which, for a surface element adjacent in a first direction and/or a second direction aligned perpendicular to the first direction to a surface element having a flat slope, and adjacent in the diagonal direction to a surface element having a throat slope, a slope is determined, wherein the surface normal of the surface element is inclined in the same direction as the surface normal of the surface element having the throat slope. This ensures optimal dewatering at every point of the surface, in that water is guided on the shortest path to the nearest dewatering point of the surface along a continuous dewatering path.

In an advantageous embodiment of the invention, the method comprises a step in which, for a surface element adjacent in a first direction and/or a second direction aligned perpendicular to the first direction to one surface element each having a throat slope, a ridge slope is determined in each case, wherein the surface normal of the surface elements intersect with the throat slope. This serves for automatically and correctly assigning the surface elements having a defined slope for optimally dewatering a surface having a slope.

In an advantageous embodiment of the invention, the method comprises a step in which, for a surface element directly adjacent to at least three, preferably three surface elements having a throat slope in a first direction and/or a second direction aligned perpendicular to the first direction, wherein a ridge slope is determined in each case, wherein the surface normal of the surface elements intersect with the throat slope, wherein the surface normal of the surface element having the ridge slope does not intersect the surface normal of the surface elements having the throat slope. A dewatering path having a monotonically decreasing slope in the direction of the dewatering point thus arises over the entire surface, and no increase of the slope unable to be overcome by the draining water occurs at any of the points. The entire surface can thus be automatically assigned and the material used can be utilized optimally, leading to savings with respect to the resources used.

In a preferred embodiment of the invention, the method comprises a step in which, for a surface element directly adjacent in a diagonal direction to a surface element having a throat slope, a slope is determined, wherein the surface element having the throat slope comprises at least one collision point in a first direction and/or in a second direction aligned perpendicular to the first direction, wherein the throat slope is monotonically increasing in the direction of the collision point and the slope is monotonically increasing and/or decreasing along the collision point. This opens up the possibility of automatically detecting and assigning surface elements having a collision point, for example at the end of a roof and/or a transition to a light well and/or a transition to an elevator shaft, so that the dewatering takes place around the collision point and water is also drained in the direction of the dewatering point even starting from said points. Water is thus guided around the collision point at said point in the direction of the dewatering point of the surface and does not flow directly toward the collision point, at which buildup of water can then occur. This ensures reliable dewatering at every point, particularly at collision points of the surface.

In a preferred embodiment of the invention, the surface is a roof surface. This opens up the possibility of automatically assigning a slope and arbitrarily many collision points, for example internal corners or roof edges, to roof surfaces and thus ensuring optimal dewatering.

In an advantageous embodiment of the method according to the invention, a configuration plan saved on a data storage medium for a surface for depicting slopes determined for individual surface elements as instructions for creating a structure of a topology for dewatering a defined, bounded surface according to the determined slopes can be obtained, wherein the plates correspond to the dimensions and/or the geometric shape of the individual surface elements. A precise description is thus available and comprises all information regarding the topology of the surface for selecting the plates required for configuring. The configuration plan further shows the arrangement of the plates relative to each other in detail, so that said plan can be used as instructions.

The object of building up the structure of a topology for dew atering a defined, bound surface, particularly a roof and/or parking deck, is achieved in that said structure is built up of individual plates, the dimensions and/or geometric shape thereof being adapted to individual surface elements according to a configuration plan according to claim 21. Such a structure of the topology ensures that water occurring at every point of the surface can drain in the direction of a dewatering point in a controlled manner and that no buildup occurs.

In an advantageous embodiment of the method according to the invention, said method is designed for implementing in a software, wherein at least one dewatering point and/or a layout plan is determined as the input value. The dewatering point can thus be indicated by the user within the layout and the optimal assigning of the corresponding surface can be simulated on this basis.

A preferred embodiment of the invention is described as an example with reference to a drawing, wherein further advantageous details can be seen in the figures of the drawing.

Functionally identical parts are thereby labeled with the same reference numeral.

The figures in the drawing show, in detail:

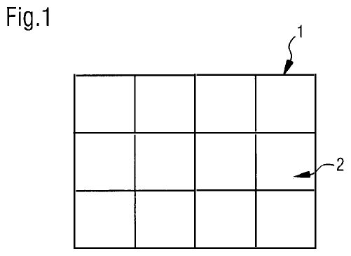

FIG. 1 a plan view of a schematic depiction of a sloped surface, divided into individual surface elements according to the method according to the invention;

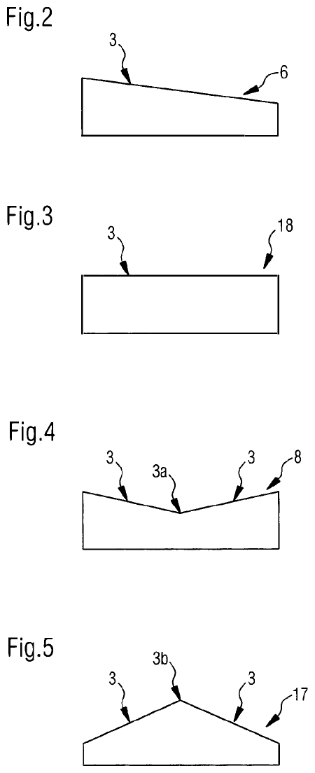

FIG. 2 a side view of a schematic depiction of a surface element having a plane, wherein the plane comprises a slope;

FIG. 3 a side view of a schematic depiction of a surface element having a plane, wherein the plane comprises a flat slope;

FIG. 4 a side view of a schematic depiction of a surface element having two planes, wherein the planes comprise a throat slope;

FIG. 5 a side view of a schematic depiction of a surface element having at least two, preferably two planes, wherein the planes comprise a ridge slope;

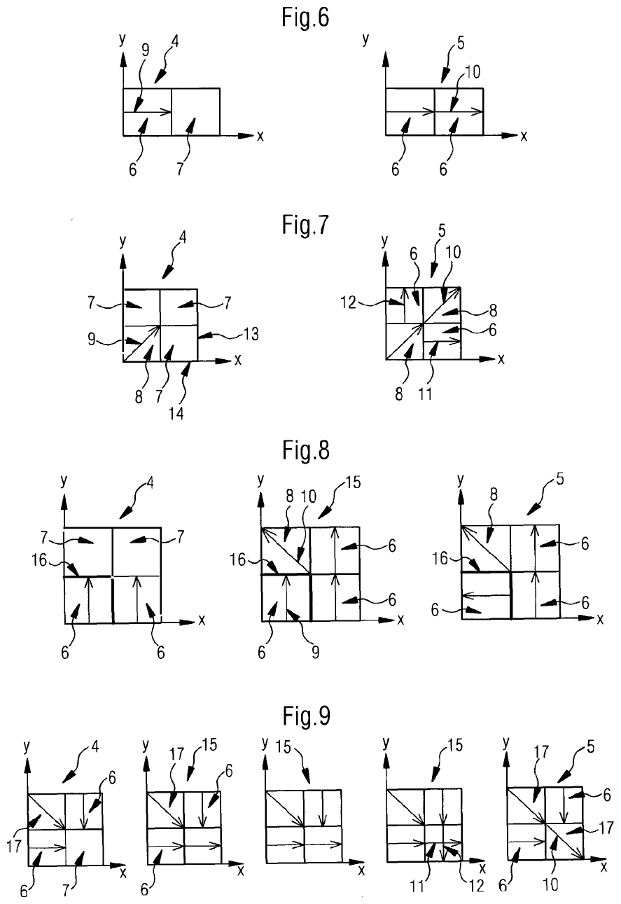

FIG. 6 a plan view of a schematic depiction of a potential initial situation of two surface elements adjacent to each other, by means of which a slope is determined for the unassigned surface elements adjacent in the X-direction, and the resulting end condition after the slope has been determined for all unassigned surface elements;

FIG. 7 a plan view of a schematic depiction of a potential initial situation of four surface elements adjacent to each other, by means of which a slope is determined for the unassigned surface elements adjacent in the X and Y-direction and the diagonal direction, and the resulting end condition after the slope has been determined for all unassigned surface elements;

FIG. 8 a plan view of a schematic depiction of a potential initial situation of four surface elements adjacent to each other, by means of which a slope is determined for the unassigned surface elements adjacent in the X and Y-direction, wherein a collision point is present between the individual surface elements, an intermediate step necessary for determining the final slope, and the resulting end condition after the slope has been determined for all unassigned surface elements;

FIG. 9 a plan view of a schematic depiction of a potential initial situation of four surface elements adjacent to each other, by means of which a slope is determined for the unassigned surface elements adjacent in the X and Y-direction and the diagonal direction, three intermediate steps necessary for determining the final slope, and the resulting end condition after the slope has been determined for the unassigned surface element;

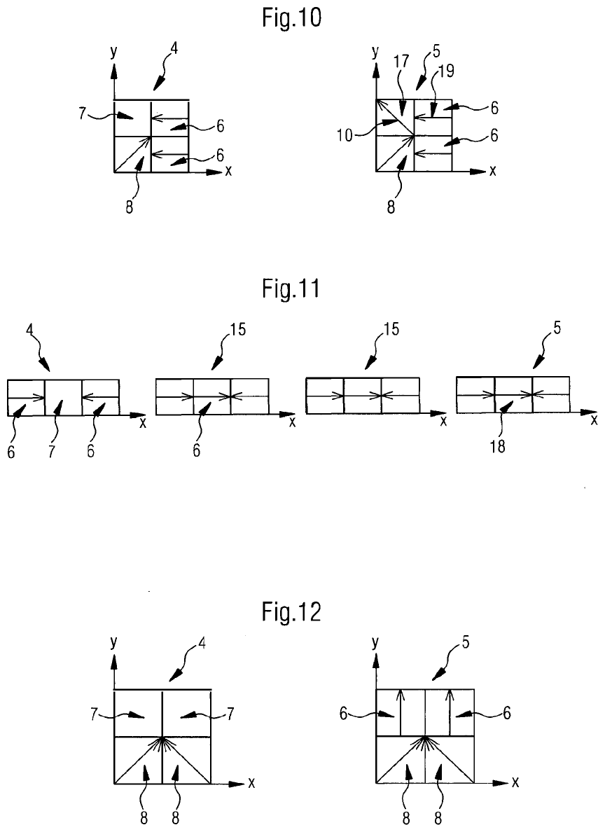

FIG. 10 a plan view of a schematic depiction of a potential initial situation of four surface elements adjacent to each other, by means of which a slope is determined for the unassigned surface element adjacent in the X and Y-direction and the diagonal direction, and the resulting end condition after the slope has been determined for the unassigned surface element;

FIG. 11 a plan view of a schematic depiction of a potential initial situation of three surface elements adjacent to each other, by means of which a slope is determined for the unassigned surface elements adjacent in the X-direction, an intermediate step necessary for determining the final slope, and the resulting end condition after the slope has been determined for all of the unassigned surface elements;

FIG. 12 a plan view of a schematic depiction of a potential initial situation of four surface elements adjacent to each other, by means of which a slope is determined for the unassigned surface elements adjacent in the X and Y-direction and the diagonal direction, and the resulting end condition after the slope has been determined for the unassigned surface elements;

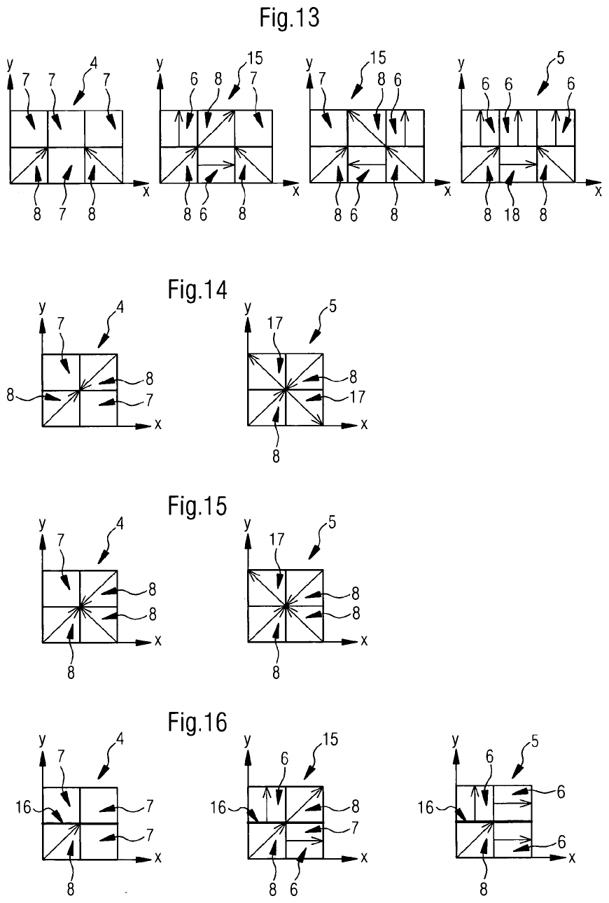

FIG. 13 a plan view of a schematic depiction of a potential initial situation of six surface elements adjacent to each other, by means of which a slope is determined for the unassigned surface elements adjacent in the X and Y-direction and in the diagonal direction, two intermediate steps necessary for determining the final slope, and the resulting end condition after the slope has been determined for the unassigned surface elements;

FIG. 14 a plan view of a schematic depiction of a potential initial situation of four surface elements adjacent to each other, by means of which a slope is determined for the unassigned surface elements adjacent in the X and Y-direction and the diagonal direction, and the resulting end condition after the slope has been determined for the unassigned surface elements;

FIG. 15 a plan view of a schematic depiction of a potential initial situation of four surface elements adjacent to each other, by means of which a slope is determined for the unassigned surface element adjacent in the X and Y-direction and the diagonal direction, and the resulting end condition after the slope has been determined for the unassigned surface element;

FIG. 16 a plan view of a schematic depiction of a potential initial situation of four surface elements adjacent to each other, by means of which a slope is determined for the unassigned surface elements adjacent in the X and Y-direction, wherein a collision point is present between the individual surface elements, an intermediate step necessary for determining the final slope, and the resulting end condition after the slope has been determined for all unassigned surface elements;

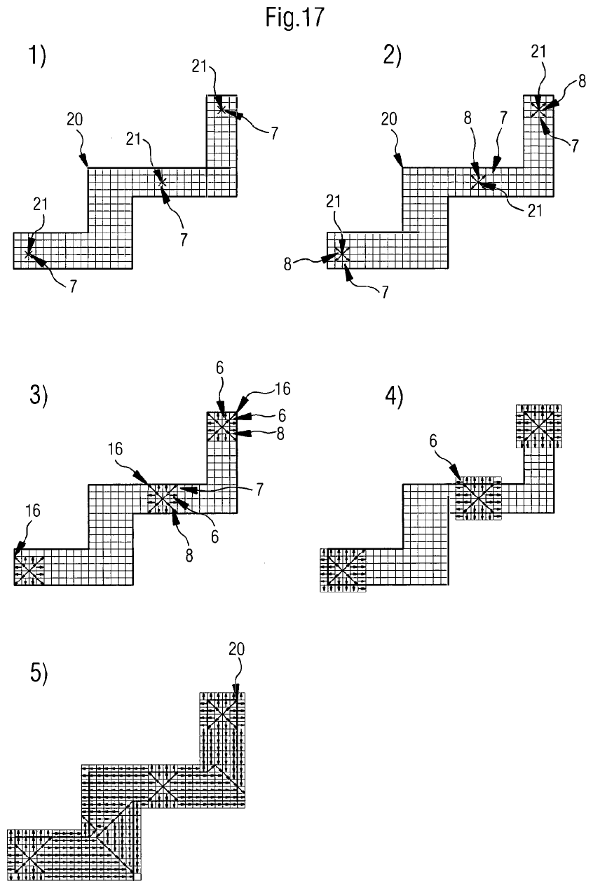

FIG. 17 a plan view of a schematic depiction of the successive determining of the slopes of the individual surface elements, starting from dewatering points within a layout of a surface, in five selected successive method steps according to the invention.

FIG. 1 shows surface 1 having a slope, divided into individual surface elements 2 according to the method according to the invention, wherein the geometric shape of the individual surface elements 2 depicts the geometric shape of the plates to be assigned to the surface 1. Such plates for assigning to surfaces made of different materials and in various standardized dimensions can be roof plates or floor plates, for example, having different slopes and a throat slope, ridge slope, slope, or flat slope, for example.

FIG. 2 shows a side view of a slope element 6 having a plane 3 in a slope. The slope of the plane is defined individually for every surface or using a DIN standard, according to the specification.

FIG. 3 shows a side view of a flat element 18 having a plane 3 in a flat slope, meaning that the slope of the plane 3 is equal to zero.

FIG. 4 shows a side view of a throat element 8 having two planes 3 aligned to each other so as to form a recess 3a across the surface element 2. Such a slope of the planes 3 is a throat slope.

FIG. 5 shows a side view of a ridge element 17 having two planes 3 aligned to each other so as to form a rise across the surface element 2. Such a slope of the planes 3 is a ridge slope.

FIG. 6 shows a plan view on the left depicting a plan view of a potential initial situation 4 prior to performing the method according to the invention. In said initial situation 4, an unassigned surface element 7 is directly adjacent to a slope element 6 in the X-direction. No slope is associated with the unassigned surface element 7. A monotonically decreasing slope in the X-direction is associated with the slope element 6. FIG. 6 shows on the right a plan view of the end condition 5, after performing the method according to the invention. It is evident therefrom that a slope has been defined for the unassigned surface element 7 in a method step according to the invention. The properties of the slope are shown by means of a three-dimensional vector, vₐ. The three-dimensional vector vₐ comprises a location vector vₐ^{bp} and a direction vector vₐ^{bk}. The height of the slope and the direction of the slope are stored in the vector vₐ. The height of the corresponding surface element 2 is stored in the location vector vₐ^{bp}. The alignment of the slope of the corresponding surface element 2 is stored in the direction vector vₐ^{bk}.

Within the method step according to the invention, the magnitude and direction of the slope for the unassigned surface element 7 directly adjacent in the X-direction are determined as a function of the properties of the slope of the original surface element stored in the three-dimensional vector vₐₗₜ 9 and stored in a three-dimensional vector vₙₑᵤ 10. A slope is thus determined for the adjacent surface element and stored in the three-dimensional vector vₙₑᵤ comprising the following components:

$$\begin{matrix}{v}_{neu}^{xp} = {v}_{alt}^{xp} + {v}_{alt}^{xk} & {v}_{neu}^{yp} = {v}_{alt}^{yp} + {v}_{alt}^{yk} & {v}_{neu}^{zp} = {v}_{alt}^{zp} + {v}_{alt}^{zk} \\ {v}_{neu}^{xk} = {v}_{alt}^{xk} & {v}_{neu}^{yk} = {v}_{alt}^{yk} & {v}_{neu}^{zk} = {v}_{alt}^{zk}\end{matrix}$$

The three-dimensional vector vₐ is always aligned opposite the direction of water flow.

FIG. 7 shows a plan view on the left depicting a potential initial situation 4 prior to performing the method according to the invention. In the present initial situation 4, a throat element 8 is directly adjacent in the X and Y-direction and in the diagonal direction to an unassigned surface element 7 for which no slope has been determined. A monotonically decreasing slope in the direction of the dewatering point is associated with the throat element 8. FIG. 7 shows on the right the end condition 5. It can be seen that the slopes for each of the adjacent surface elements 2 have been determined in a method step according to the invention. The surface elements adjacent in the X and Y-direction are slope elements 6. The surface element adjacent in the diagonal direction is a throat element 8.

A slope is determined for the surface elements adjacent in the X and Y-direction and is stored in the three-dimensional vectors v_{dx} 11 and v_{dy} 12 having the components

$$\begin{matrix}{v}_{neu}^{xp} = {v}_{alt}^{xp} + \frac{{g}_{b}}{2} & {v}_{neu}^{yp} = {v}_{alt}^{yp} + {v}_{alt}^{yk} & {v}_{neu}^{zp} = {v}_{alt}^{zp} + {v}_{alt}^{zk} \\ {v}_{neu}^{xk} = - {g}_{b} & {v}_{neu}^{yk} = {v}_{alt}^{yk} & {v}_{neu}^{zk} = {v}_{alt}^{zk}\end{matrix}$$

$$and$$

$$\begin{matrix}{v}_{dy}^{xp} = {v}_{alt}^{xp} + sgn ( {v}_{alt}^{xk} ) * \frac{{g}_{b}}{2} ; {v}_{dy}^{yp} = {v}_{alt}^{yp} + {v}_{alt}^{yk} ; {v}_{dy}^{zp} = {v}_{alt}^{zp} + {v}_{alt}^{zk} \\ {v}_{dx}^{xk} = 0 ; {v}_{dy}^{yk} = {v}_{alt}^{yk} ; {v}_{dy}^{zk} = {v}_{alt}^{zk} .\end{matrix}$$

where gₕ is the length of the surface element 13 and g_{b} is the width of the surface element 14, and sgn is the signum function.
A throat slope is determined for the surface element adjacent in the diagonal direction and is stored in the three-dimensional vector vₙₑᵤ 10 having the components

$$\begin{matrix}{v}_{neu}^{xp} = {v}_{alt}^{xp} + {v}_{alt}^{xk} & {v}_{neu}^{yp} = {v}_{alt}^{yp} + {v}_{alt}^{yk} & {v}_{neu}^{zp} = {v}_{alt}^{zp} + {v}_{alt}^{zk} \\ {v}_{neu}^{xk} = {v}_{alt}^{xk} & {v}_{neu}^{yk} = {v}_{alt}^{yk} & {v}_{neu}^{zk} = {v}_{alt}^{zk} .\end{matrix}$$

FIG. 8 shows a plan view on the left depicting a potential initial situation 4 prior to performing the method according to the invention. In the present initial situation 4, two slope elements 6 directly adjacent to each other in the X-direction are directly adjacent to two unassigned surface elements 7 in the Y-direction, wherein a collision point 16, for example a light well or an elevator shaft, is present between the slope elements 6 and the unassigned surface element 7. The middle depiction of FIG. 8 shows an intermediate step 15 of the method according to the invention. In the present intermediate step 15, the slopes for the two unassigned surface elements 7 adjacent in the Y-direction are determined, wherein the collision point 16 must be taken into consideration, as the slope must be determined so that water is guided around the collision point 16. It is evident from the middle depiction of FIG. 8 that the surface element adjacent to the collision point 16 in the Y-direction is a throat element 8, so that a throat slope has been determined, and water is thus guided around the collision point 16 in the recess 3a implementing a throat element. The surface element adjacent to the slope element 6 in the Y-direction is also a slope element 6, as a slope has been determined.

The throat slope determined for the surface element directly adjacent in the Y-direction is stored in the three-dimensional vector vₙₑᵤ 10 having the components

$$\begin{matrix}{v}_{neu}^{xp} = {v}_{alt}^{xp} + \frac{{g}_{b}}{2} & {v}_{neu}^{yp} = {v}_{alt}^{yp} + {v}_{alt}^{yk} & {v}_{neu}^{zp} = {v}_{alt}^{zp} + {v}_{alt}^{zk} \\ {v}_{neu}^{xk} = - {g}_{b} & {v}_{neu}^{yk} = {v}_{alt}^{yk} & {v}_{neu}^{zk} = {v}_{alt}^{zk} .\end{matrix}$$

From the right depiction of FIG. 8 showing the end condition 5, after performing a method step according to the invention, it is evident that the slope of the slope element 6 adjacent to the collision point 16 is rotated 90° away from the collision point 16 and is also a slope. Water is thus also guided around the collision point 16 by said slope element 6.

Depending on the location of the collision point 16 and the alignment of the slope of the slope element 6 in the initial situation 4, a total of eight cases are differentiated. If a slope element 6 is sloped in the Y-direction and adjacent to a collision point 16, a slope is determined for the throat element 8 adjacent to the collision point 16 in the Y-direction and is stored in the three-dimensional vector vₙₑᵤ 10 having the components

$$\begin{matrix}{v}_{neu}^{xp} = {v}_{alt}^{xp} + {v}_{alt}^{xk} & {v}_{neu}^{yp} = {v}_{alt}^{yp} - \frac{{g}_{h}}{2} & {v}_{neu}^{zp} = {v}_{alt}^{zp} + {v}_{alt}^{zk} \\ {v}_{neu}^{xk} = {v}_{alt}^{xk} & {v}_{neu}^{yk} = {g}_{h} & {v}_{neu}^{zk} = {v}_{alt}^{zk}\end{matrix}$$

for the 1st or 2nd quadrant, or the three-dimensional vector vₙₑᵤ 10 having the components

$$\begin{matrix}{v}_{neu}^{xp} = {v}_{alt}^{xp} + {v}_{alt}^{xk} & {v}_{neu}^{yp} = {v}_{alt}^{yp} + \frac{{g}_{h}}{2} & {v}_{neu}^{zp} = {v}_{alt}^{zp} + {v}_{alt}^{zk} \\ {v}_{neu}^{xk} = {v}_{alt}^{xk} & {v}_{neu}^{yk} = - {g}_{h} & {v}_{neu}^{zk} = {v}_{alt}^{zk}\end{matrix}$$

for the 3rd or 4th quadrant.

If a slope element 6 is sloped in the X-direction and adjacent to a collision point 16, a slope is determined for the throat element 8 adjacent to the collision point 16 in the X-direction and is stored in the three-dimensional vector vₙₑᵤ 10 having the components

$$\begin{matrix}{v}_{neu}^{xp} = {v}_{alt}^{xp} + \frac{{g}_{b}}{2} & {v}_{neu}^{yp} = {v}_{alt}^{yp} + {v}_{alt}^{yk} & {v}_{neu}^{zp} = {v}_{alt}^{zp} + {v}_{alt}^{zk} \\ {v}_{neu}^{xk} = - {g}_{b} & {v}_{neu}^{yk} = {v}_{alt}^{yk} & {v}_{neu}^{zk} {=}_{alt}^{zk}\end{matrix}$$

for the 1st or 3rd quadrant, or the three-dimensional vector vₙₑᵤ 10 having the components

$$\begin{matrix}{v}_{neu}^{xp} = {v}_{alt}^{xp} - \frac{{g}_{b}}{2} & {v}_{neu}^{yp} = {v}_{alt}^{yp} + {v}_{alt}^{yk} & {v}_{neu}^{zp} = {v}_{alt}^{zp} + {v}_{alt}^{zk} \\ {v}_{neu}^{xk} = {g}_{b} & {v}_{neu}^{yk} = {v}_{alt}^{yk} & {v}_{neu}^{zk} = {v}_{alt}^{zk}\end{matrix}$$

for the 2nd or 4th quadrant.

The slope of the slope element 6 is determined in a final step as rotated 90° away from the collision point 16 in each case.

FIG. 9 shows in the left depiction a plan view of a further potential initial situation 4 prior to performing the method according to the invention. In the present initial situation 4, one slope element 6 is adjacent in the X and Y-direction and a ridge element 17 is adjacent in the diagonal direction to an unassigned surface element 7. From the three middle depictions of FIG. 9, it is evident that two slope elements 6 are theoretically present in the unassigned surface element 7 after performing the intermediate steps 15, the slope thereof being aligned in different directions. The slope of the slope elements is stored in each of the three-dimensional vectors v_{dx} 11 and v_{dy} 12.

In reality, reliable dewatering of the surface element would not be thereby guaranteed. Therefore, a ridge slope is determined for the surface element. Water is thus drained by means of the two planes of the ridge element 17 sloped toward each other. In the end condition 5, shown in the right depiction of FIG. 9 in a plan view, a ridge element having a ridge slope is adjacent to the two slope elements 6 in the X and Y-direction.

The ridge slope is stored in the three-dimensional vector vₙₑᵤ 10 having the components vₙₑᵤ^{xk}=v_{dx}^{xk}+v_{dy}^{xk}; vₙₑᵤ^{yk}=v_{dx}^{yk}+v_{dy}^{yk}; vₙₑᵤ^{zk}=max{v_{dx}^{zk}, v_{dy}^{zk}}

and

$${v}_{neu}^{xp} = \{ \begin{matrix}{v}_{dy}^{xp} , {v}_{dx}^{xk} = 0 \\ {v}_{dy}^{xp} - sgn ( {v}_{dx}^{xk} ) * \frac{{g}_{h}}{2} , {v}_{dx}^{xk} = 0\end{matrix} ; {v}_{neu}^{yp} = \text{} \{ \begin{matrix}{v}_{dy}^{yp} - sgn ( {v}_{dx}^{yk} ) * \frac{{g}_{b}}{2} , {v}_{dx}^{yk} = 0 \\ {v}_{dy}^{yp} , {v}_{dx}^{yk} = 0\end{matrix} ; {v}_{neu}^{zp} = {v}_{alt}^{zp} + {v}_{neu}^{zk} .$$

In the present slope addition step, the two three-dimensional vectors v_{dx} 11 and v_{dy} 12 are added together and the three-dimensional vector vₙₑᵤ 10 is thus generated.

FIG. 10 shows in the left depiction a plan view of a further potential initial situation 4 prior to performing the method according to the invention. In said initial situation 4, the unassigned surface element 7 is adjacent to a slope element 6 in the X-direction, wherein the slope is monotonically increasing in the direction of the unassigned surface element 7. In the Y-direction, the unassigned surface element 7 is adjacent to a throat element 8. The right depiction of FIG. 10 shows the end condition 5 after performing the method according to the invention, from which it is evident that a ridge element 17 has been determined for the unassigned surface element 7, after a ridge slope has been determined. The ridge slope is stored in the three-dimensional vector vₙₑᵤ having the components

$$\begin{matrix}{v}_{neu}^{xp} = {v}_{alt}^{xp} + {v}_{alt}^{xk} & {v}_{neu}^{yp} = {v}_{alt}^{yp} + {v}_{alt}^{yk} & {v}_{neu}^{zp} = {v}_{alt}^{zp} + {v}_{alt}^{zk} \\ {v}_{neu}^{xk} = {v}_{alt}^{xk} + 2 * {v}_{diag}^{xk} & {v}_{neu}^{yk} = {v}_{alt}^{yk} + 2 * {v}_{diag}^{yk} & {v}_{neu}^{zk} = max \{ {v}_{alt ,}^{zk} {v}_{diag}^{zk} \} .\end{matrix}$$

The slope of the slope element 6 is thereby stored in the three-dimensional vector v_{diag} 19.

FIG. 11 shows in the left depiction a plan view of a further potential initial situation 4 prior to performing the method according to the invention. In said initial situation 4, an unassigned surface element 7 is adjacent to a slope element 6 in the X-direction in each case. In an intermediate step 15, a slope is first determined for the unassigned surface element 7. In a next intermediate step 15, the slope element 6 is directly adjacent to a further slope element 6, wherein the two slope elements 6 have different heights, so that a step would arise at the transition, at which water could accumulate. An adapting of the heights is therefore performed, in that the greater of the two heights is used as the initial height for a flat slope. From the right depiction in FIG. 11, the end condition 5 is evident in a plan view. The flat element 18 is adjacent in the positive and negative X-directions to a slope element 6, so that water can flow in both directions from the flat element 18 in the direction of the slope elements.

FIG. 12 shows in the left depiction a plan view of a further potential initial situation 4 prior to performing the method according to the invention. In the present initial situation 4, unassigned surface elements 7 are adjacent in the Y-direction to throat elements directly adjacent to each other in the X-direction, wherein the throat slope is aligned away from each other. From the right depiction of FIG. 12, showing the end condition 5, it is evident that, by means of the method according to the invention, for surface elements directly adjacent in the Y-direction to surface elements having a throat slope, a slope is determined, wherein the throat slope is aligned away from each other, wherein the slope is monotonically decreasing in the direction of the throat elements 8. Reliable dewatering by means of the slope elements 6 is thus possible.

FIG. 13 shows in the left depiction a plan view of a further potential initial situation 4 prior to performing the method according to the invention. In the present initial situation 4, an unassigned surface element 7 is adjacent in the positive and negative X-direction to a throat element 8 in each case. In the Y-direction, unassigned surface elements 7 are adjacent to the throat element 8 and to the unassigned surface element 7. In a first intermediate step 15, a slope is determined for the unassigned surface elements 7 adjacent to the first throat element in the X and Y-direction. A throat slope is determined for the unassigned surface element adjacent to the first throat element in the diagonal direction. In a second intermediate step 15, slopes would also be theoretically determined for surface elements adjacent to the second throat element in the X and Y-direction, but would be sloped in precisely opposite directions as the slopes for the slope element determined in the first intermediate step. For the surface element adjacent in the diagonal direction, a throat slope would be determined in the same way, and also would be sloped in precisely the opposite direction as the throat slope determined in the first intermediate step 15. Because this would not enable dewatering, and can result in buildup of the water, an automatic adjustment of the slope takes place with a corresponding new determination. The end condition 5 thus achieved is shown on the right in FIG. 13. It is evident that a flat slope is determined for the surface element present between the two throat elements 8 in the X-direction. The height of the flat element 18 corresponds to the height of the throat element 8 having the greater height, so that water can drain from the flat element 18 in all directions. The slope elements 6 adjacent in the Y-direction dewater due to the slope thereof in the direction of the throat elements 8.

FIG. 14 shows in the left depiction a plan view of a further potential initial situation 4 prior to performing the method according to the invention. In the present initial situation 4, unassigned surface elements 7 are adjacent in the X and/or Y-direction to a throat element 8. The two throat elements 8 are adjacent to each other in the diagonal direction, wherein the two throat element 8 are sloped away from each other. In order to ensure reliable dewatering of every point, a ridge slope is determined for the unassigned surface element 7 adjacent in the X and/or Y-direction. From the right depiction in FIG. 14, the end condition 5 is evident, in which the ridge elements 17 are monotonically decreasing in the direction of the throat elements 8.

FIG. 15 shows in the left depiction a plan view of a further potential initial situation 4 prior to performing the method according to the invention. In the present initial situation 4, an unassigned surface element 7 is directly adjacent to three throat elements 8 in the X and/or Y-direction and in the diagonal direction. From the right depiction of FIG. 15, it is evident that a ridge slope is determined in a method step according to the invention. The ridge element 17 is monotonically decreasingly sloped in the direction of the throat elements 8, so that dewatering is also guaranteed in the present end condition.

FIG. 16 shows in the left depiction a plan view of a further potential initial situation 4 prior to performing the method according to the invention. In the present initial situation 4, a throat element 8 is directly adjacent to three unassigned surface elements 7 in the X and/or Y-direction and in the diagonal direction, wherein a collision point 16 is present between the individual surface elements, for example a roof edge or a light well. In a first intermediate step 15, a slope is determined for the surface elements adjacent in the X and Y-directions and for the surface element adjacent in the diagonal direction. It is evident from the middle depiction of FIG. 16 that the throat element 8 adjacent in the diagonal direction to the collision point 16 would dewater in the direction of the collision point 16, so that buildup of the water would thus occur at the collision point 16 if the collision point 16 is implemented as an elevator shaft 16, for example. If the collision point 16 were implemented as a roof edge, and the throat element 8 were to dewater in the direction thereof, the water would potentially run over the roof edge 16 and reach the façade, causing contamination. Water should always be guided around the collision point.

In this case, therefore, a slope in the direction parallel to the collision point 16 is determined for the surface element adjacent to the throat element 8 adjacent to the collision point 8. The right depiction of FIG. 16 shows the end condition 5, in which the slope element 6 dewaters along the roof edge 16.

In the first depiction of FIG. 17, a layout 20 of a surface having three dewatering points 21 is evident. As can be seen in the second depiction of FIG. 17, starting from the dewatering points 21, throat slopes are determined for the four directly adjacent unassigned surface elements 7 and are monotonically decreasing in the direction of the corresponding dewatering point, so that water arriving at the surface flows in the direction of the dewatering point. It is evident in the third depiction of FIG. 17 that, starting from the throat elements 8 adjacent to the dewatering point 21, successively for every unassigned surface element 7 further adjacent in the X and Y-directions and diagonal direction, a slope is determined as a function of the slope of the adjacent surface elements. According to the initial situation in each case, a slope is determined for each unassigned surface element 7 according to the method steps described above. The slope of a surface element is thereby always determined so that dewatering takes place from each point of the surface 1 into a dewatering point 21. To this end, each slope must be determined so that water is guided around every collision point 16 and so that buildup does not occur at any point on the surface 1.

In the fifth depiction of FIG. 17, a slope is determined for all surface elements within the layout 20, and each of the surface elements is assigned a three-dimensional vector in which the magnitude and direction of the slope is stored. The end of the method according to the invention is thus reached.

### LIST OF REFERENCE NUMERALS

1 Surface

2 Surface element

3 Plane

3a Recess

3b Rise

4 Initial situation

5 End condition

6 Slope element

7 Unassigned surface element

8 Throat element

9 Three-dimensional vector vₐₗₜ

10 Three-dimensional vector vₙₑᵤ

11 Three-dimensional vector v_{dx}

12 Three-dimensional vector v_{dy}

13 Length of the surface element gₕ

14 Width of the surface element g_{b}

15 Intermediate step

16 Collision point

17 Ridge element

18 Flat element

19 Three-dimensional vector v_{diag}

20 Layout

21 Dewatering point

What is claimed is:

1. Computer-implemented method for determining a topology of a defined bounded surface for dewatering said surface using at least one specified dewatering point, so that the surface has a monotonically increasing slope starting from the dewatering point to a collision point, wherein the topology is determined by dividing the surface into individual surface elements each having at least one plane and, starting from the dewatering point, successively determining in every plane for each surface element a slope in a first direction and/or a second direction aligned perpendicular to the first direction in order to form the surface with the monotonically increasing slope starting from the dewatering point to the collision point, wherein a throat slope is determined for at least one surface element directly adjacent to the dewatering point in that the respective surface element is divided into at least two planes and the associated surface normals intersect.

2. (canceled)

3. The method according claim 1, wherein the at least two planes of a surface element having at least one of a throat slope implement a recess in the diagonal direction along the surface element or having a ridge slope implement a rise in the diagonal direction along the surface element.

4. The method claim 1 claim 1, wherein a magnitude and/or direction of the slope of the at least two planes of a surface element is determined as a function of the slope of the at least two planes of the surface elements adjacent in a diagonal direction and/or in a first direction and/or in a second direction aligned perpendicular to the first direction.

5. The method claim 1, wherein a throat slope is determined for a surface element directly adjacent in a diagonal direction to a surface element having a throat slope.

6. The method claim 1, wherein a slope is determined for a surface element adjacent in a first direction and/or a second direction aligned perpendicular to the first direction to a surface element having a throat slope, in that a slope of a plane of the surface element is determined as monotonically increasing and/or decreasing in a first direction and/or a second direction aligned perpendicular to the first direction.

7. The method claim 1, wherein a slope is determined for a surface element adjacent in a first direction and/or a second direction aligned perpendicular to the first direction to a surface element having a slope.

8. The method claim 1, wherein the slope is determined as a throat slope for a surface element adjacent in a first direction and/or a second direction perpendicular to the first direction to a surface element having a slope, wherein the surface element having the slope in a first direction and/or in a second direction perpendicular to the first direction comprises at least one collision point and is determined as a throat slope.

9. The method claim 1, wherein the slope of a plane of a surface element having a slope in the direction of at least one collision point is determined as a slope offset from the collision point by 90°.

10. The method claim 1, wherein for a plane of a surface element adjacent to a surface element having a slope in a first direction and/or in a second direction aligned perpendicular to the first direction, wherein the slopes are each aligned toward each other, a flat slope is determined, wherein the slope of the plane is zero, wherein the magnitude of the slope is equal to the magnitude of the slope of the adjacent surface element having the greater magnitude.

11. The method claim 1, wherein a ridge slope is determined for a surface element adjacent in a first direction and/or a second direction aligned perpendicular to the first direction to a surface element having a throat slope, and adjacent in the diagonal direction to a surface element having a slope, wherein the at least two planes of the surface element intersect and/or are inclined in the opposite direction of the slope of the surface normal of the surface element having the throat slope in a first direction and/or in a second direction aligned perpendicular to the first direction.

12. (canceled)

13. The method claim 1, wherein for a surface element in which two slopes are perpendicular to each other in different directions, a ridge slope is determined.

14. The method claim 1, wherein for a surface element directly adjacent in a first direction and/or in a second direction aligned perpendicular to the first direction and/or in a diagonal direction to at least two surface elements having a throat slope directly adjacent to each other in a first direction and/or in a second direction aligned perpendicular to the first direction, wherein the throat slope is monotonically increasing in the direction of a point in each case, a slope is determined, wherein the surface normal of the surface element is parallel to the surface normal of the surface element having the throat slope.

15. The method claim 1, wherein for a surface element present between two surface elements each having a throat slope in the first direction and/or in the second direction aligned perpendicular to the first direction, wherein the throat slope is monotonically increasing in the direction of a point in each case, a flat slope is determined, wherein the magnitude of the slope is determined to be the magnitude of the slope of the adjacent surface element having the greater magnitude.

16. The method claim 1, wherein a slope is determined for a surface element adjacent in the diagonal direction to a surface element having a throat slope and/or adjacent in a first direction and/or a second direction perpendicular to the first direction to a surface element having a flat slope, wherein the surface normal of the surface element is inclined in the same direction as the surface normal of the surface element having the throat slope.

17. The method claim 1, wherein for a surface element adjacent to a surface element having a throat slopein a first direction and/or in a second direction aligned perpendicular to the first direction, one ridge slope each is determined, wherein the at least two planes of the surface element intersect.

18. The method claim 1, wherein for a surface element directly adjacent to at least three surface elements having a throat slope in a first direction and/or in a second direction aligned perpendicular to the first direction, a ridge slope is determined, wherein the surface normal of the surface elements intersect with the throat slope, wherein the surface normal of the surface element having the ridge slope does not intersect the surface normal of the surface elements having the throat slope.

19. The method claim 1, wherein for a surface element directly adjacent in a diagonal direction to a surface element having a throat slope, a slope is determined, wherein the surface element having the throat slope comprises at least one collision point in a first direction and/or in a second direction aligned perpendicular to the first direction, wherein the throat slope is monotonically increasing in the direction of the collision point and the slope is monotonically increasing or decreasing along the collision point.

20. The method claim 1, wherein the surface is a roof surface.

21. A configuration plan saved on a data storage medium for a surface for depicting slopes determined for individual surface elements as instructions for creating a structure of a topology for dewatering a defined bounded surface according to the determined slopes, wherein the configuration plan comprises at least one dimension and a geometric shape for the individual surface elements, respectively, in order to configure the surface by a plurality of plates having the dimension and geometric shape, wherein the configuration plan is generated by means of an automated method according to one of claims 1, wherein the individual surface elements comprise at least one plane with the slope being determined for the surface element, respectively, and wherein the surface elements form the surface with the monotonically increasing slope starting from the dewatering point to the collision point, wherein at least one surface element directly adjacent to the dewatering point has a throat slope in that the respective surface element is divided into at least two planes and the associated surface normals intersect.

22. A structure of a topology for dewatering a defined bounded surface, particularly a roof and/or parking deck, wherein said structure is built of individual plates, the dimensions and geometric shape thereof being adapted to individual surface elements according to a configuration plan according to claim 21, wherein the individual plates comprise at least one plane with the slope being determined for the plate, respectively, and wherein the plates form a surface with a monotonically increasing slope starting from the dewatering point to the collision point, wherein at least one plate directly adjacent to the dewatering point has a throat slope in that the respective plate is divided into at least two planes and the associated surface normals intersect.

23. A software comprising instructions, which, when being executed by a computer, cause the computer to carry out the method according to claim 1, wherein at least one dewatering point and/or a layout plan is determined as the input value.
